(19) United States
(12) Patent Application Publication
(10) Pub. No.: US 2017/0257104 A1
(43) Pub. Date: Sep. 7, 2017

(54) METHOD FOR ROBUST PHASE-LOCKED LOOP DESIGN

(71) Applicant: QUALCOMM Incorporated, San Diego, CA (US)

(72) Inventors: Hongchun Yu, Shanghai (CN); Weiran Lin, Shanghai (CN); Shuguang Li, Shanghai (CN); Guangming Yin, Corona del Mar, CA (US)

(21) Appl. No.: 15/428,059

(22) Filed: Feb. 8, 2017

(30) Foreign Application Priority Data
Mar. 3, 2016 (CN) PCT/CN2016/075533

(51) Int. Cl. H03L 7/081; H04L 7/033

(52) U.S. Cl. CPC H03L 7/0814; H04L 7/0331

(57) ABSTRACT

Systems, methods, and apparatus are disclosed that that can improve robustness of digital phase locked loop (PLL) circuits. A method performed by a clock generation device includes generating a plurality of phase-shifted signals, each of the plurality of phase-shifted signals having a phase shift with respect to a base clock signal that is unique within the plurality of phase-shifted signals, selecting a first phase-shifted signal as an output signal, generating a first phase control word indicative of a second phase-shifted signal when the second signal has a closer phase relationship with a reference signal than the first signal, refraining from selecting the second signal as the output signal while either of the first signal and the second signal is in a first signaling state, and selecting as the output signal, the second signal when the first signal and the second signal are in a second signaling state.

### CROSS-REFERENCE TO RELATED APPLICATIONS

The present Application for patent claims priority to pending WO Application No. PCT/CN2016/075533, titled “METHOD FOR ROBUST PHASE-LOCKED LOOP DESIGN” filed Mar. 3, 2016, and assigned to the assignee hereof and hereby expressly incorporated by reference herein as if fully set forth below and for all applicable purposes.

### TECHNICAL FIELD

The present disclosure relates generally to device configurations used for clock generation, and more particularly, to digital phase-locked loop devices that employ phase rotator circuits.

### BACKGROUND

Phase-locked loop (PLL) circuits used to generate signals with a phase that is locked to, tracks, or is otherwise related to the phase of a reference signal. One or more feedback signals are used to maintain the phase of output signals generated by a PLL circuit in a desired relationship with the phase of the reference signal. An output signal generated by a PLL circuit may have a frequency that is related to the frequency of the reference signal. In one example, the output signal produced by the PLL circuit may have a frequency that is a multiple of the frequency of the reference signal. PLL circuits may be used in variety of devices including in radio frequency (RF) interfaces.

Digital PLL circuits may include a digital phase detector, and a frequency divider to ensure that the frequency of the output signal of the PLL circuit is a multiple of the frequency of the reference signal. The digital phase detector produces feedback indicating whether the phase of the output signal leads or lags the phase of the reference signal. The PLL circuit may lock the frequency of the output signal to the desired frequency based on the feedback. In digital PLLs, changes in feedback produced by a digital phase detector can cause irregularities in the format and timing of the output signal. With the continuous increase in operating frequency of communications devices, the irregularities in format and timing of the output signal of a PLL may cause malfunctioning and/or loss of synchronization in some instances. Accordingly, there is a continuing need for improved robustness in PLL circuits.

### SUMMARY

Certain aspects of the disclosure relate to systems, apparatus, methods and techniques that can improve robustness of digital PLL circuits. In some embodiments, a phase rotator circuit adapted according to certain aspects disclosed herein prevent glitches and shortened pulse widths from occurring in signals generated by a digital PLL.

In various aspects of the disclosure, a method performed by a clock generation device includes generating a plurality of phase-shifted signals, each of the plurality of phase-shifted signals having a phase shift with respect to a base clock signal that is unique within the plurality of phase-shifted signals; selecting as an output signal, a first signal in the plurality of phase-shifted signals; generating a first phase control word indicative of a second signal in the plurality of phase-shifted signals when the second signal has a closer phase relationship with a reference signal than the first signal; refraining from selecting the second signal as the output signal while either of the first signal and the second signal is in a first signaling state; and selecting as the output signal, the second signal when the first signal and the second signal are in a second signaling state.

In various aspects of the disclosure, an apparatus includes a first phase rotation circuit configured to select an output signal from a plurality of phase-shifted signals derived from a base clock signal, each of the plurality of phase-shifted signals having a phase shift with respect to a base clock signal that is unique within the plurality of phase-shifted signals; a first control word generator adapted to produce phase control words that select an output signal from the plurality of phase-shifted signals as an output signal; a timing control circuit adapted to provide a first control word produced by the first control word generator to the first phase rotation circuit after a delay when the first control word is configured to change the output signal by selecting a first signal that has a closer phase relationship with a reference signal than the output signal. The delay may prevent the timing control circuit from providing the first control word to the first phase rotation circuit while either of the first signal and the second signal is in a first signaling state.

In various aspects of the disclosure, a clock generation apparatus includes means for generating a plurality of phase-shifted signals, each of the plurality of phase-shifted signals having a phase shift with respect to a base clock signal that is unique within the plurality of phase-shifted signals; means for selecting as an output signal, a first signal in the plurality of phase-shifted signals; means for generating a first phase control word indicative of a second signal in the plurality of phase-shifted signals when the second signal has a closer phase relationship with a reference signal than the first signal; means for refraining from selecting the second signal as the output signal while either of the first signal and the second signal is in a first signaling state; and means for selecting as the output signal, the second signal when the first signal and the second signal are in a second signaling state.

### BRIEF DESCRIPTION OF THE DRAWINGS

FIG. 1 depicts an apparatus that may be adapted according to certain aspects disclosed herein.

FIG. 2 illustrates a phase rotator circuit that may be adapted in accordance with certain aspects disclosed herein.

FIGS. 3 and 4 illustrate irregularities in timing of output signals generated using a phase rotator circuit.

FIG. 5 illustrates techniques for avoiding glitches in a PLL circuit adapted in accordance with certain aspects disclosed herein.

FIG. 6 illustrates a timing control circuit that may be included in a PLL circuit adapted in accordance with certain aspects disclosed herein.

FIG. 7 illustrates timing in a PLL circuit that includes multiple phase rotator circuits and adapted in accordance with certain aspects disclosed herein.

FIG. 8 illustrates a timing adjustment circuit that may be used to stabilize sampling clocks during certain phase jumps in a PLL circuit that has been adapted in accordance with certain aspects disclosed herein.

FIG. 9 is a block diagram illustrating an example of an apparatus employing a processing circuit that may be adapted according to certain aspects disclosed herein.

FIG. 10 is a flowchart of a method in accordance with certain aspects disclosed herein.

FIG. 11 is a diagram illustrating an example of a hardware implementation for an apparatus according to certain aspects disclosed herein.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

### Overview

Certain digital PLL devices are adapted to select an output signal from a plurality of signals that are phase-shifted versions of a source clock signal. The signal derived from the source clock signal that has a phase that best matches the phase of a reference signal may be selected as the output signal. From time-to-time, a change in the output signal may be necessitated when a difference and/or variability in frequencies of the source clock signal or the reference signal causes the phase relationship between the source clock signal and the reference signal to change. In order to effect a change in the output signal, a different one of the plurality of signals derived from the source clock signal may be selected as the output signal. The digital PLL may generate a control word that selects the signal in the plurality of signals as the output signal.

Certain aspects disclosed herein relate to apparatus and methods that control the timing of changes in the selection of phase-shifted version of a source signal. In one example, a phase rotation circuit in a PLL generates a phase control word that causes a switch from a first signal with a first phase shift relative to a reference signal to a second signal that has a leading or lagging phase relationship with the first signal. The phase control word may be sampled using a third signal that is phase-shifted with respect to the first signal, and the second signal.

### Example of an Apparatus Employing One or More PLLs

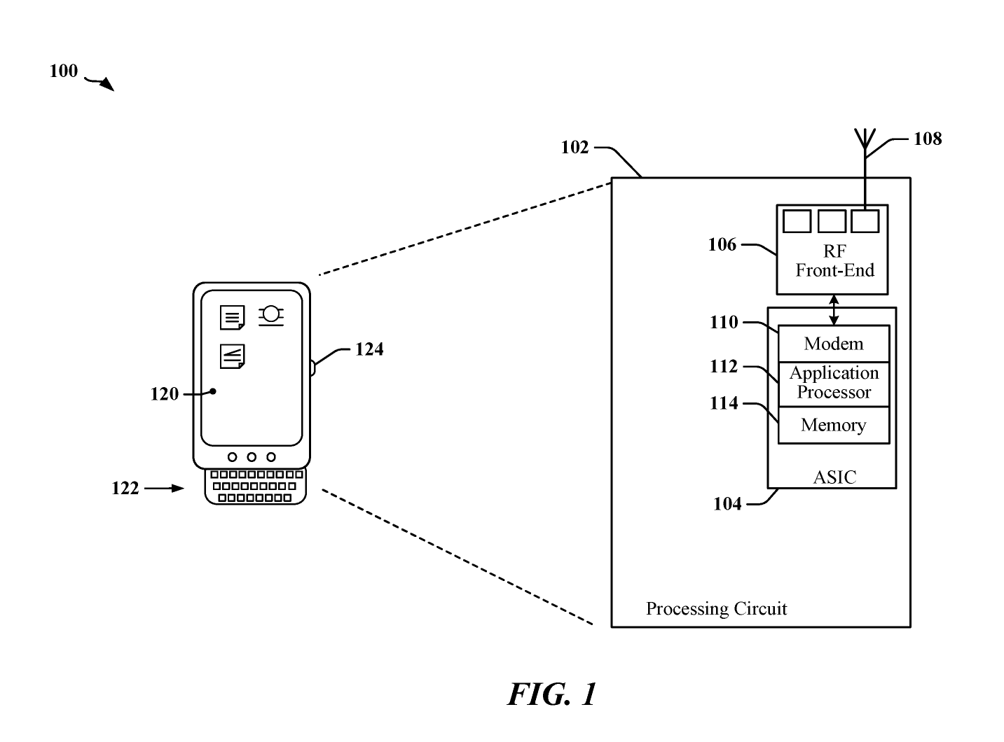

Certain aspects of the invention may be applicable to electronic devices that are subcomponents of a communications apparatus. The apparatus may be a wireless telephone, a mobile computing device, a wearable processing device such as a smart watch, an appliance, automobile electronics, avionics systems, for example. FIG. 1 depicts an example of such an apparatus 100. The apparatus 100 may include a processing circuit 102 having multiple devices or circuits embodied therein. The processing circuit 102 may be implemented in an application-specific IC (ASIC) and/or a system-on-chip (SoC) that may include multiple devices or circuits that communicate with one another in accordance with a clock signal. In one example, the apparatus 100 may be a wireless communication device and the processing circuit 102 may include an RF transceiver that include an RF front-end circuit 106, including intermediate frequency (IF) circuits and baseband processors configured to enable the apparatus to communicate wirelessly through one or more antennas 108 with a radio access network, a core access network, the Internet and/or another network. The processing circuit may include PLLs used to generate clock signals for inter-device communication, as well as RF clock signals, IF clock signals and baseband clock signals used in the RF front-end circuit 106.

In the example illustrated in FIG. 1, the processing circuit 102 includes an ASIC device 104 that may include one or more processors 112, modems 110, processor readable storage such as a memory 114, and/or other logic circuits or functions. The processing circuit 102 may be controlled by an operating system and may provide an application programming interface (API) layer that enables the processor 112 to execute software modules residing in the memory 114. The software modules may include instructions and data stored in the memory 114 and/or in different IC devices. The ASIC device 104 may access on-board memory 114 and/or memory provided external to the ASIC device 104 or processing circuit 102, including read-only memory (ROM) or random-access memory (RAM), electrically erasable programmable ROM (EEPROM), flash cards, or any memory device that can be used in processing systems and computing platforms. The processing circuit 102 may include or have access to a local database or other parameter storage that can maintain operational parameters and other information used to configure and operate the apparatus 100 and/or the processing circuit 102. The local database may be implemented using a database module, flash memory, magnetic media, EEPROM, optical media, tape, soft or hard disk, or the like. The processing circuit 102 may also be operably coupled to external devices such as the antennas 108, a display 120, operator controls, such as a button 124 and/or an integrated or external keypad 122, among other components. A user interface may communicate with one or more peripherals such as the display 120, keypad 122, etc. through a peripheral connector bus or through one or more peripheral communication links.

Certain aspects herein relate to digital PLL circuits that generate clock signals, including clock signals used for inter-device communication, and clock signals used in the RF front-end circuit 106 such as RF clock signals, IF clock signals, and baseband clock signals. A digital PLL circuit may employ a phase rotator circuit to select between phase-shifted versions of a base clock in order to maintain a desired relationship between a generated clock signal and a reference signal.

### Example of a Phase Rotator Circuit

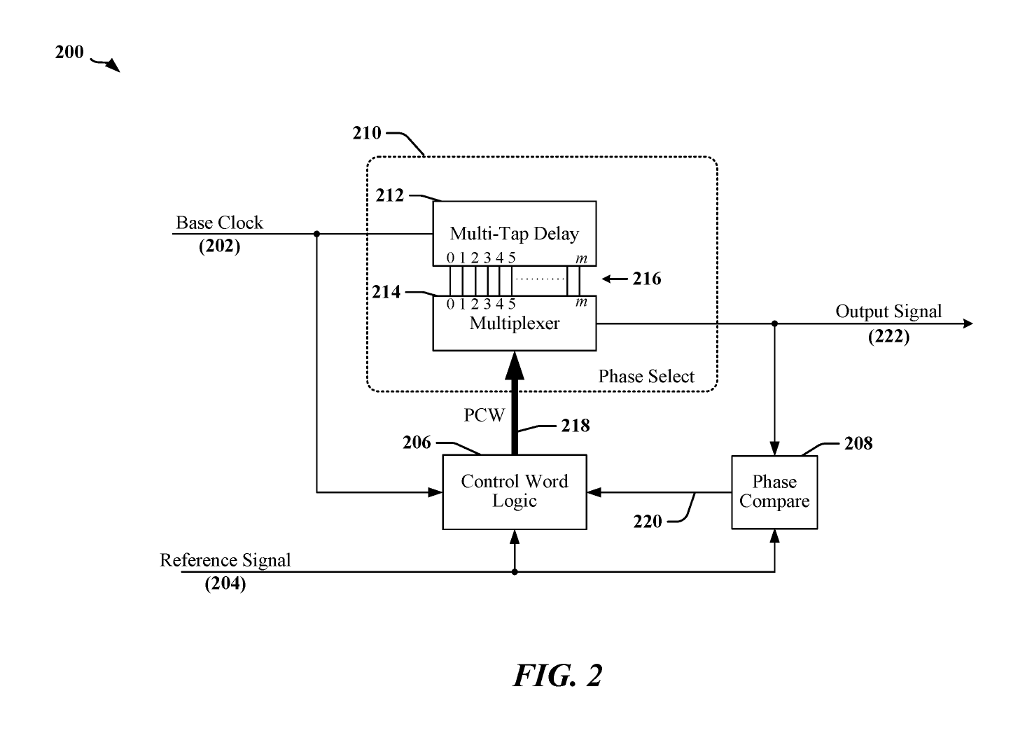

FIG. 2 illustrates certain aspects of a phase rotator circuit 200 that may be used in a digital PLL circuit. In the example, the phase rotator circuit 200 receives a base clock signal 202 and a reference signal 204. The base clock signal 202 may be derived from a voltage controlled oscillator or other clock generator. The reference signal 204 may be a signal of interest provided by an RF front-end circuit 106 or received from a transceiver used for wired communication between devices within an apparatus or for communication with an external device, for example. The phase rotator circuit 200 may be adapted to maintain a desired phase relationship between the base clock signal 202 and the reference signal 204.

In operation, the phase rotator circuit 200 selects between phases signals 216 to produce an output signal 222. The phase signals 216, which may also be referred to herein as phases, are phase-shifted versions of the base clock signal 202. Phase selection is implemented using a phase control word (PCW) 218 to select between phase signals 216 based on the current difference in phase between the base clock signal 202 and the reference signal 204. The PCW 218 may be changed when the phase of the reference signal 204 rotates with respect to the base clock 202 and produces a phase difference between the base clock signal 202 and the reference signal 204 that exceeds a threshold value. In one example, the control word may change when the phase difference between a current phase signal selected as the output signal 222 and the reference signal 204 is greater than the phase difference between another of the phase signals 216 and the reference signal 204. There may be a time lag between detecting a phase difference between the output signal 222 and the reference signal 204 and the selection of a different one of the phase signals 216 as the output signal 222. The time lag may be measurable in multiples of the period of the base clock 202 and/or output signal 222.

According to certain aspects, the base clock signal 202 is provided to a multi-tap delay circuit 212 that produces p phase signals 216. Neighboring pairs of phase signals 216 are separated by a fixed phase shift, which may be calculated as (360°/p). A multiplexer 214 receives the phase signals 216 and selects one of the phase signals 216 to produce the output signal 222. The multiplexer 214 selects between the phase signals 216 using a PCW 218 provided by control word generating logic 206. The control word generating logic 206 may include or cooperate with a phase detection or comparison circuit 208 that compares the phase of the output signal 222 with the phase of the reference signal 204 and produces a difference signal 220 used to configure a next PCW 218. The phase rotator circuit 200 may select between neighboring signals within the phase signals 216, which are identified herein as {Pₙ₋₁, Pₙ, Pₙ₊₁, Pₙ₊₂, . . . }, where the Pₙ signal leads the Pₙ₊₁ signal and lags the Pₙ₊₁ signal by a phase shift of 360°/p.

In some instances, changes in the PCW 218 may occur at times that cause irregularities in the output signal 222, of a type that may be based on timing determining when the PCW 218 is sampled and/or applied by the phase select circuit 210. Examples of irregularities include glitches caused by introduction of additional transitions, and shortened pulse width caused by pulse swallows.

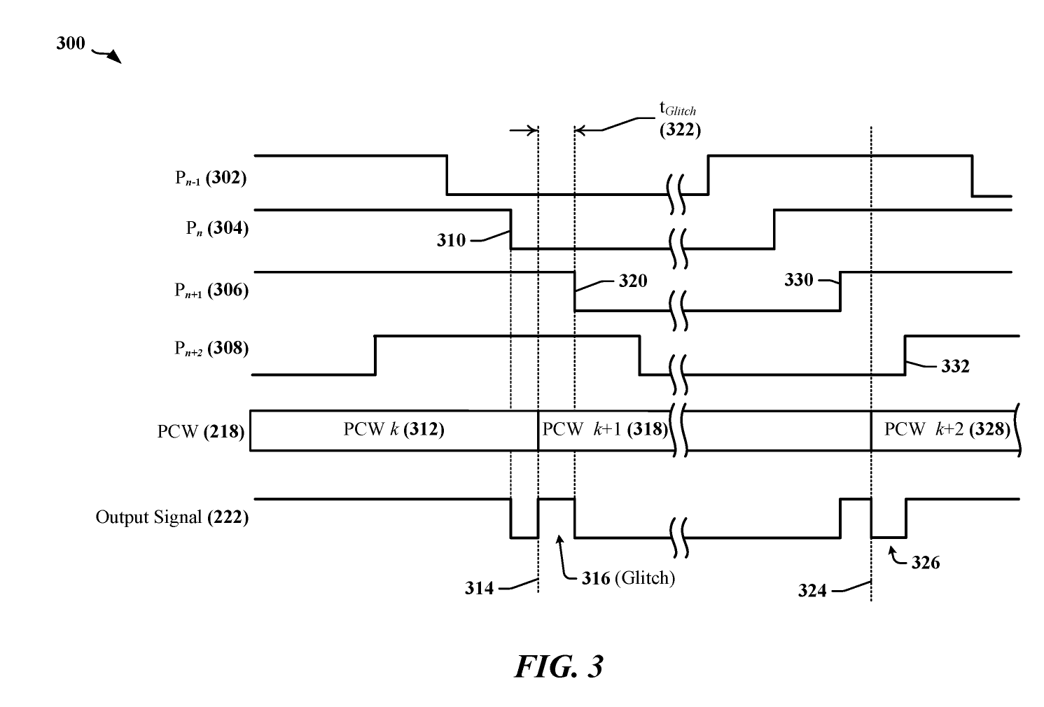

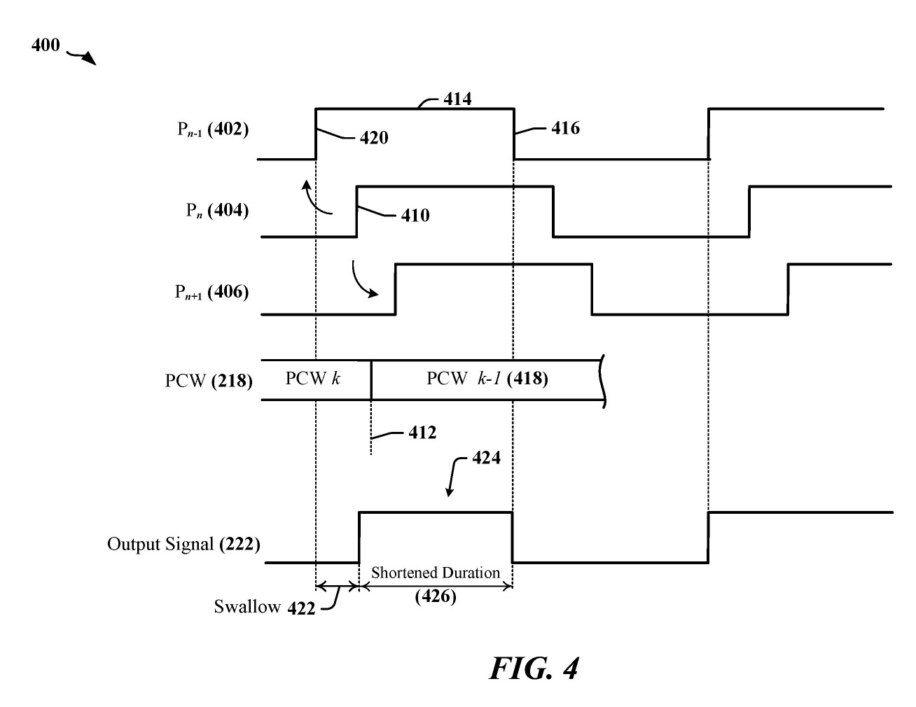

FIGS. 3 and 4 are timing diagrams 300, 400 that illustrate irregularities in the output signal 222 arising from control word timing. For the purposes of illustration, control words may be sampled using a signal that is selected from the phase signals 216 produced by, or used by the phase select circuit 210. The examples illustrated in the timing diagrams 300, 400 relate to a transition from a current phase to a lagging causing a glitch 316, 326, or from a current phase to a leading phase resulting in a shortened pulse 424 where a portion 422 of the pulse 424 has been swallowed. The timing of the transition in successive control words determines whether a glitch or swallow occurs within the time slot of the neighboring phase.

In the first timing diagram 300 a transition from a first control word 312 to a second control word 318 occurs at a first time 314, after a falling edge 310 on the current phase signal, which may initially be a first Phase Signal 304. The transition from the first control word 312 to the second control word 318 occurs before the corresponding falling edge 320 on the neighboring second Phase Signal 306, which lags the first Phase Signal 304. The second control word 318 may cause selection of the second Phase Signal 306 as the output signal 222. Before selection of the second Phase Signal 306, the output signal 222 is in a low signaling state having followed the first Phase Signal 304, and the output signal 222 transitions high when the second Phase Signal 306 is selected. The second Phase Signal 306 then transitions low after a short period of time (t_{Glitch}) 322, resulting in the introduction of a glitch 316 in the output signal 222. The second Phase Signal 306 may then be considered to be the current phase signal.

A transition in the PCW 218 from the second control word 318 to a third control word 328 occurs at a second time 324, after a rising edge 330 on the second Phase Signal 306 but before the corresponding rising edge 332 on the third Phase Signal 308, which lags the second Phase Signal 306. The third control word 328 may cause selection of the third Phase Signal 308 as the output signal 222. Before selection of the third Phase Signal 308, the output signal 222 is in a high signaling state having followed the second Phase Signal 306, and the output signal 222 transitions low when the third Phase Signal 308 is selected. The third Phase Signal 308 then transitions high after a short period of time, resulting in a glitch 326 in the output signal 222.

In the second timing diagram 400 a transition in control words occurs at a time 412. The PCW 218 transitions to a next control word 418 after a rising edge 410 on the current Phase Signal 404 and after the corresponding rising edge 420 on the neighboring leading Phase Signal 402. The control word 418 causes selection of the leading Phase Signal 402 as the output signal 222 and, since the Phase Signal 402 transitions from the high signaling state 414 before the Phase Signal 404, the output signal 222 has a pulse 424 with a duration 426 that is truncated with respect to the duration of the high signaling state 414 of the Phase Signal 402. Accordingly, a portion 422 of the output signal 222 corresponding to the time when the leading Phase Signal 402 is in the high signaling state 414 and the initial Phase Signal 404 is in a low signaling state has been swallowed due to the timing of the control word 418. Swallowing may occur at negative or positive transitions of the output signal 222.

The occurrences of glitches 316 and partially swallowed pulses can result in errors and other malfunctions. In some instances, glitches 316 may be interpreted as additional pulses or, when filters are employed that remove the glitches 316, some pulses 424 with shortened durations 426 may be inadvertently removed by the filters.

Improving Robustness of a Digital PLL

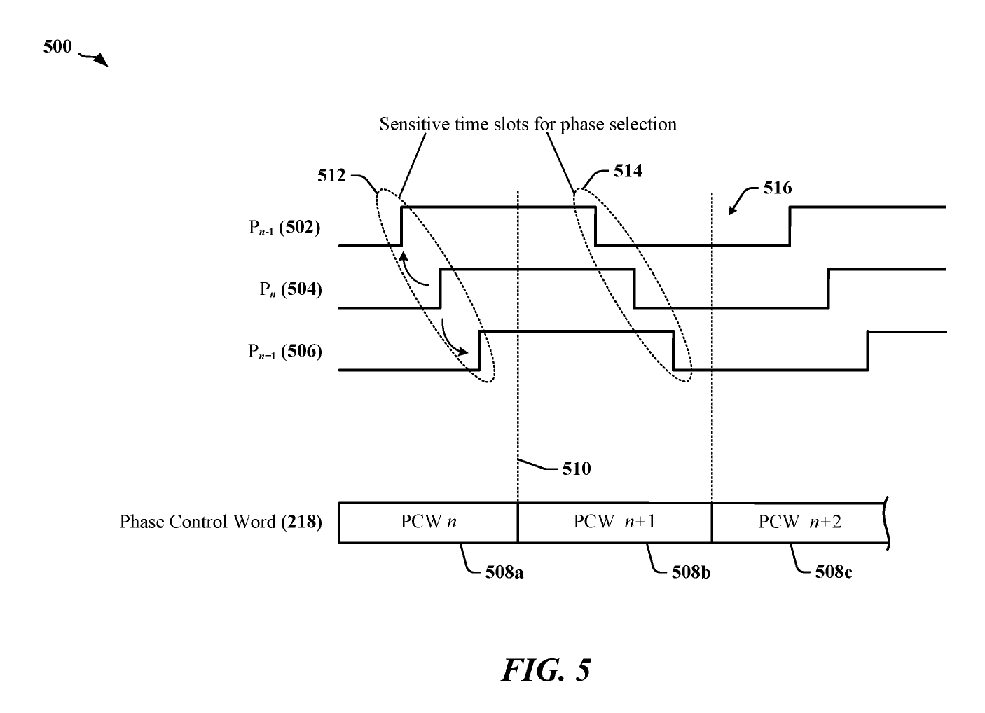

A PLL adapted according to certain aspects disclosed herein may enable a digital PLL to suppress glitches and/or prevent swallows in a manner that is insensitive to variations introduced by process, temperature, kick noise, and voltage. FIG. 5 is a timing diagram 500 that illustrates certain aspects of a circuit adapted to avoid the generation of glitches. It may be desirable to avoid changing phases between neighboring phase signals 502, 504, 506, during sensitive time intervals 512, 514 when one or more of the phase signals 502, 504, 506 are transitioning.

A phase rotator circuit may be adapted in accordance with certain aspects disclosed herein such that the timing of changes in the PCW 218 are propagated to the phase selection circuit 210 at a time outside the time intervals 512, 514 when the phase signals 502, 504, 506 are transitioning. In one example, a phase rotator circuit outputs two phase control words (n phase control word and n+m phase control word), where the n+m phase control word selects a phase signal that is used to sample the n phase control word. The n phase control word transitions at times outside the time intervals 512, 514 encompassing transitions of the current phase signal 504 and the neighboring phase signals 502, 506. Time intervals 512, 514 relate to rising edges and falling edges, respectively. A timing control circuit may be provided in the phase select circuit 210 that controls timing of the multiplexer 214. The timing control circuit may respond to the n+m phase control word by changing a sampling delay of a working clock used by the phase rotator circuit 210.

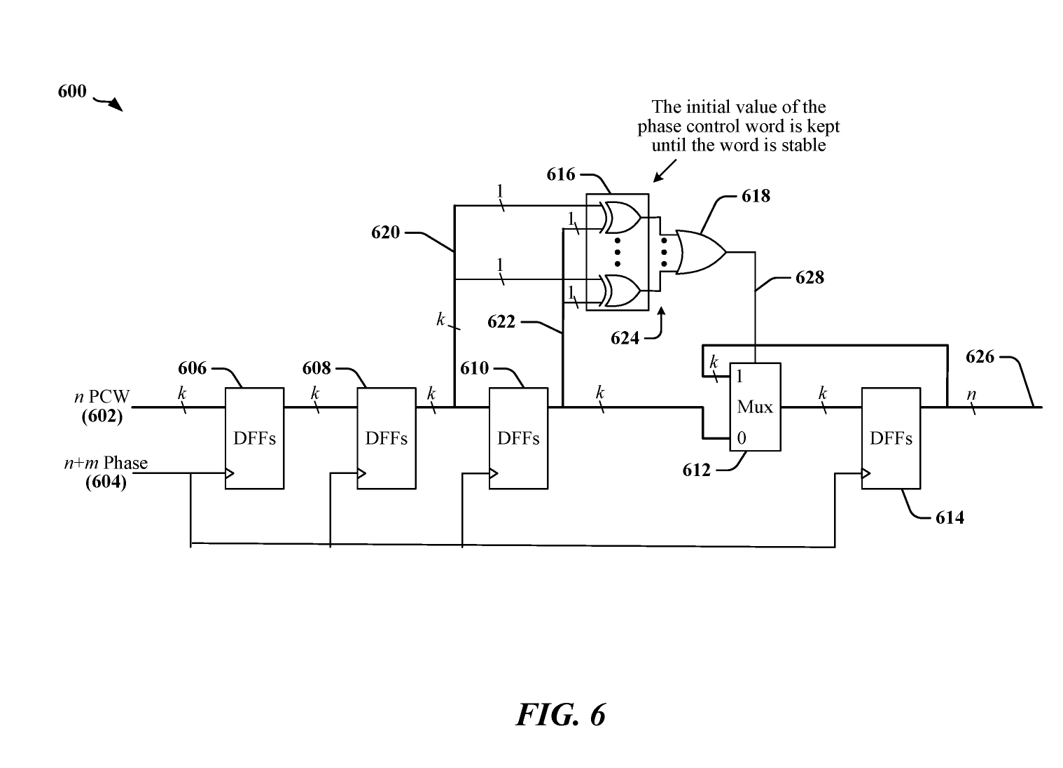

FIG. 6 illustrates an example of a timing control circuit 600 that may be included in a phase rotator circuit 210. The multi-bit n phase control word 602 is sampled by a first set of D-flip-flops 606 under control of a sampling phase signal 604 that is selected by the n+m phase control word. The word sampled by the first set of D-flip-flops 606 is resampled twice by consecutive sets of of D-flip-flops 608, 610, which are clocked by the sampling phase signal 604. Two or more resampled words 620, 622 are compared using, for example, a set of exclusive-OR gates 616 to compare individual bits of the resampled words 620, 622, and an OR gate 618 receiving the outputs 624 of the exclusive-OR gates 616 to determine if any differences exist between the resampled words 620, 622. The output 628 of the OR gate 618 is used to control a multiplexer 612 that selects between the second resampled word 622 and the current output 626 of the timing control circuit 600 to provide an input to an output set of D flip-flops 614. The output set of D flip-flops 614 captures the delayed control word 602 and provides the output 626 of the timing control circuit 600. When the resampled words 620, 622 are equal to each other, the gating logic (Phase Signal 402 and multiplexer 612) permit the n phase control word 602 to progress to the final stage (D flip-flops 614) of the timing control circuit 600, thereby providing a de-glitch for control words. Using the sampling phase signal 604 ensures that the change of phase control word occurs outside the outside the time intervals 512, 514 defined by transitions of the current phase signal 504, and the neighboring phase signals 502, 506.

The duration of a pulse on the output signal 222 may be variable. Some phase jumps are not delayed and other phase jumps are subject to variable delays. The timing control circuit 600 may be further adapted to adjust the timing of the processing of phase control words. In one example, the sampling delay of the working clock of phase rotator may be modified to produce pulse widths on the output signal that lie within a predefined range of durations.

In some modes of operation an indicator signal may be generated to select sampling phases based on the type of phase change to be performed. The indicator signal may indicate whether a phase control word is intended to adjust the output signal using a leading or lagging phase. For lagging phase, the sampling phase has a phase n+m (as illustrated in FIG. 5). For changes to a leading phase, the sampling phase may have a phase n+m′, where n is the current phase and m′ is selected to guarantee the change of phase control word occurs outside the time slot defined by the n−1, n, and n+1 phases and to guarantee that the current phase clock and the next phase clock (i.e., the target of the adjustment) are both at low voltage level. In some examples, m′ is greater than m, and is also greater than half the number of overall phases.

In some modes of operation, the falling edge of a sampling phase with a phase n+m may be used to sample leading phase adjustment phase control words. In one example, a single parameter m may configure operations of the system. In another example, m′ may be defined as m′=m+(p/2), where p is the number of overall phases. In another example, the sampling phase has a phase n+(p−1) for sampling leading phase adjustment phase control words. The latter example may be equivalent to sampling phase control words using n−1, and the phase switch may be made at a point between the rising/falling edge of current phase and the leading phase.

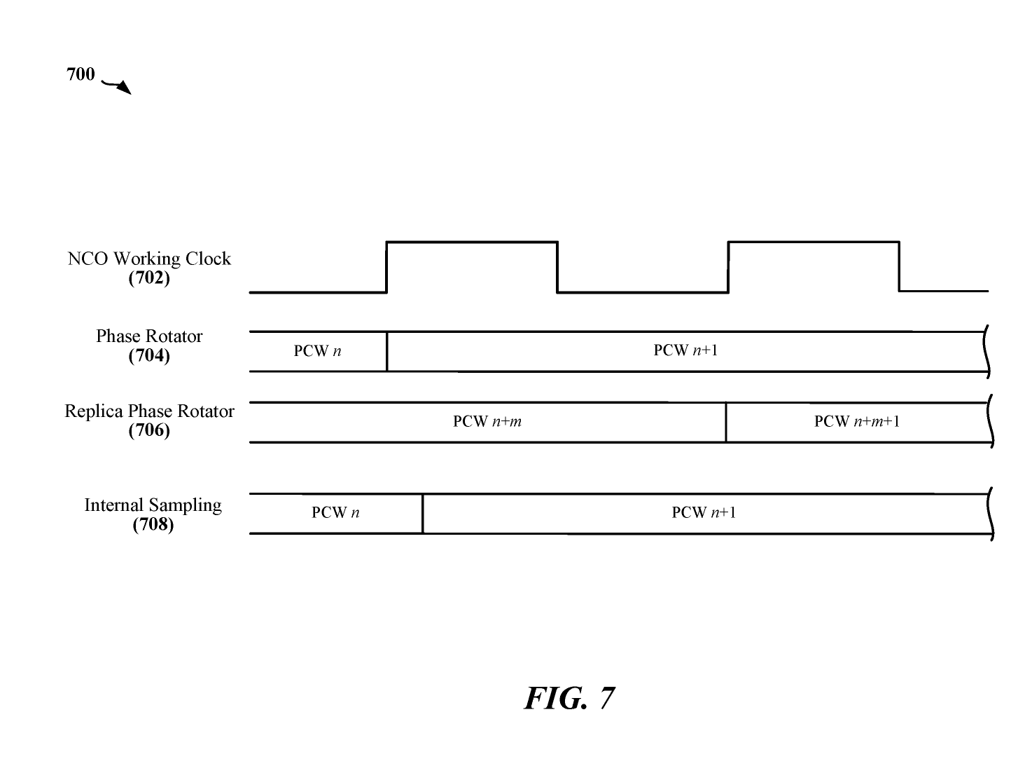

According to certain aspects, multiple phase rotators may be employed in a PLL circuit. A first phase rotator circuit may be used to generate a working clock, and phase rotator circuits may be used to select two or more sampling phases. In some instances, a single phase rotator circuit may be configurable to generate sampling clocks for rising and falling edges corresponding to leading or lagging phase transitions. A multiplexer may select the sampled phase control words based on the indicator of leading or lagging phase. FIG. 7 illustrates timing in a PLL circuit that includes multiple phase rotator circuits.

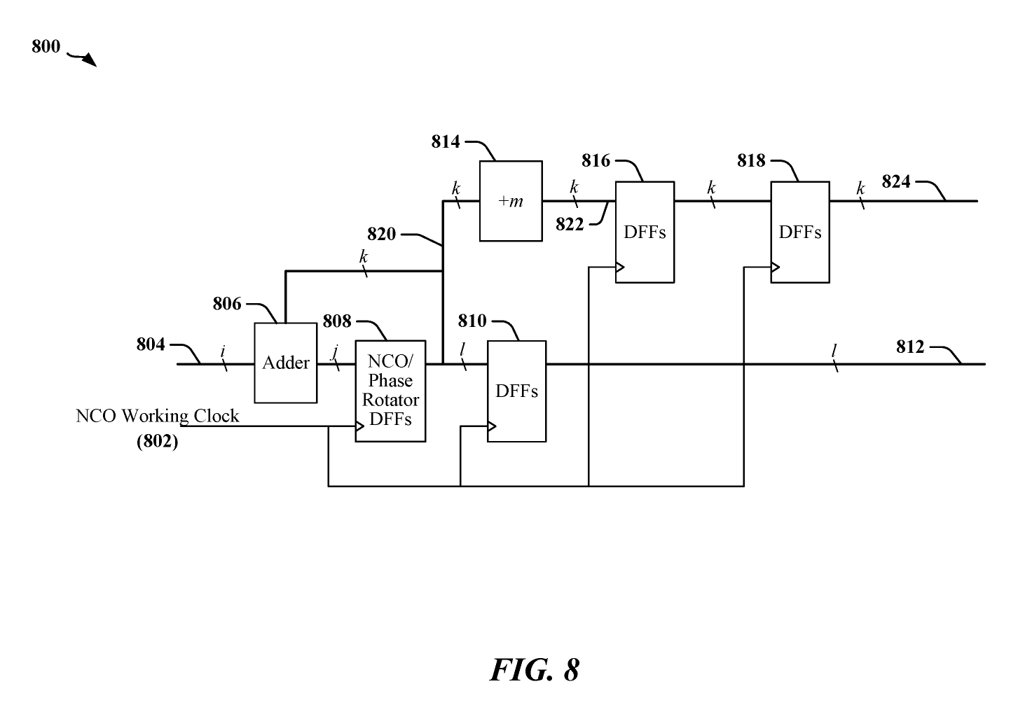

FIG. 8 illustrates a timing adjustment circuit 800 that may be used to stabilize sampling clocks during certain phase jumps. For example, phase control word sampling is not needed when no phase jump is to be performed, and some latency may be permitted. A clock signal 802 provided by a numerically controlled oscillator (NCO) may be used to sample phase control words used by the NCO and one or more phase rotators. A first adder 806 may be added to an output 820 of the first set of D flip-flops 808 for each cycle of the clock signal 802. The n+m phase control word is generated using the output of the first set of D flip-flops 80, and a second adder 814 that adds the +m value to obtain an n+m phase control word 822 the n+m phase control word 822 is sampled and resampled by the second and third D flip-flops 816, 818 to produce an output n+m phase control word 824. The NCO phase control word 812 is obtained by sampling the output 820 of the first set of D flip-flops 808 using a third set of D flip-flops 810.

### Examples of Processing Circuits and Methods

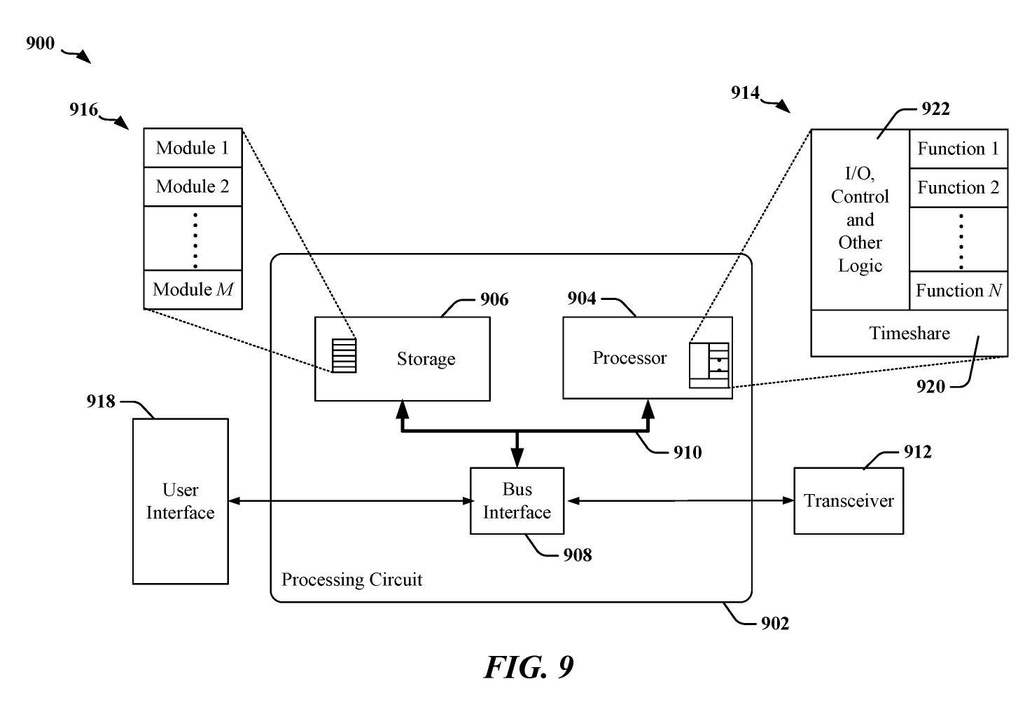

FIG. 9 is a conceptual diagram illustrating a simplified example of a hardware implementation for an apparatus 900 employing a processing circuit 902 that may be configured to perform one or more functions disclosed herein. In accordance with various aspects of the disclosure, an element, or any portion of an element, or any combination of elements as disclosed herein may be implemented using the processing circuit 902. The processing circuit 902 may include one or more processors 904 that are controlled by some combination of hardware and software modules. Examples of processors 904 include microprocessors, microcontrollers, digital signal processors (DSPs). ASICs, field programmable gate arrays (FPGAs), programmable logic devices (PLDs), state machines, sequencers, gated logic, discrete hardware circuits, and other suitable hardware configured to perform the various functionality described throughout this disclosure. The one or more processors 904 may include specialized processors that perform specific functions, and that may be configured, augmented or controlled by one of the software modules 916. The one or more processors 904 may be configured through a combination of software modules 916 loaded during initialization, and further configured by loading or unloading one or more software modules 916 during operation.

In the illustrated example, the processing circuit 902 may be implemented with a bus architecture, represented generally by the bus 910. The bus 910 may include any number of interconnecting buses and bridges depending on the specific application of the processing circuit 902 and the overall design constraints. The bus 910 links together various circuits including the one or more processors 904, and storage 906. Storage 906 may include memory devices and mass storage devices, and may be referred to herein as computer-readable media and/or processor-readable media. The bus 910 may also link various other circuits such as timing sources, timers, peripherals, voltage regulators, and power management circuits. A bus interface 908 may provide an interface between the bus 910 and one or more transceivers 912. A transceiver 912 may be provided for each networking technology supported by the processing circuit. In some instances, multiple networking technologies may share some or all of the circuitry or processing modules found in a transceiver 912. Each transceiver 912 provides a means for communicating with various other apparatus over a transmission medium. Depending upon the nature of the apparatus 900, a user interface 918 (e.g., keypad, display, speaker, microphone, joystick) may also be provided, and may be communicatively coupled to the bus 910 directly or through the bus interface 908.

A processor 904 may be responsible for managing the bus 910 and for general processing that may include the execution of software stored in a computer-readable medium that may include the storage 906. In this respect, the processing circuit 902, including the processor 904, may be used to implement any of the methods, functions and techniques disclosed herein. The storage 906 may be used for storing data that is manipulated by the processor 904 when executing software, and the software may be configured to implement any one of the methods disclosed herein.

One or more processors 904 in the processing circuit 902 may execute software. Software shall be construed broadly to mean instructions, instruction sets, code, code segments, program code, programs, subprograms, software modules, applications, software applications, software packages, routines, subroutines, objects, executables, threads of execution, procedures, functions, algorithms, etc., whether referred to as software, firmware, middleware, microcode, hardware description language, or otherwise. The software may reside in computer-readable form in the storage 906 or in an external computer readable medium. The external computer-readable medium and/or storage 906 may include a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a “flash drive,” a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium and/or storage 906 may also include, by way of example, a carrier wave, a transmission line, and any other suitable medium for transmitting software and/or instructions that may be accessed and read by a computer. Computer-readable medium and/or the storage 906 may reside in the processing circuit 902, in the processor 904, external to the processing circuit 902, or be distributed across multiple entities including the processing circuit 902. The computer-readable medium and/or storage 906 may be embodied in a computer program product. By way of example, a computer program product may include a computer-readable medium in packaging materials. Those skilled in the art will recognize how best to implement the described functionality presented throughout this disclosure depending on the particular application and the overall design constraints imposed on the overall system.

The storage 906 may maintain software maintained and/or organized in loadable code segments, modules, applications, programs, etc., which may be referred to herein as software modules 916. Each of the software modules 916 may include instructions and data that, when installed or loaded on the processing circuit 902 and executed by the one or more processors 904, contribute to a run-time image 914 that controls the operation of the one or more processors 904. When executed, certain instructions may cause the processing circuit 902 to perform functions in accordance with certain methods, algorithms and processes described herein.

Some of the software modules 916 may be loaded during initialization of the processing circuit 902, and these software modules 916 may configure the processing circuit 902 to enable performance of the various functions disclosed herein. For example, some software modules 916 may configure internal devices and/or logic circuits 922 of the processor 904, and may manage access to external devices such as the transceiver 912, the bus interface 908, the user interface 918, timers, mathematical coprocessors, and so on. The software modules 916 may include a control program and/or an operating system that interacts with interrupt handlers and device drivers, and that controls access to various resources provided by the processing circuit 902. The resources may include memory, processing time, access to the transceiver 912, the user interface 918, and so on.

One or more processors 904 of the processing circuit 902 may be multifunctional, whereby some of the software modules 916 are loaded and configured to perform different functions or different instances of the same function. The one or more processors 904 may additionally be adapted to manage background tasks initiated in response to inputs from the user interface 918, the transceiver 912, and device drivers, for example. To support the performance of multiple functions, the one or more processors 904 may be configured to provide a multitasking environment, whereby each of a plurality of functions is implemented as a set of tasks serviced by the one or more processors 904 as needed or desired. In one example, the multitasking environment may be implemented using a timesharing program 920 that passes control of a processor 904 between different tasks, whereby each task returns control of the one or more processors 904 to the timesharing program 920 upon completion of any outstanding operations and/or in response to an input such as an interrupt. When a task has control of the one or more processors 904, the processing circuit is effectively specialized for the purposes addressed by the function associated with the controlling task. The timesharing program 920 may include an operating system, a main loop that transfers control on a round-robin basis, a function that allocates control of the one or more processors 904 in accordance with a prioritization of the functions, and/or an interrupt driven main loop that responds to external events by providing control of the one or more processors 904 to a handling function.

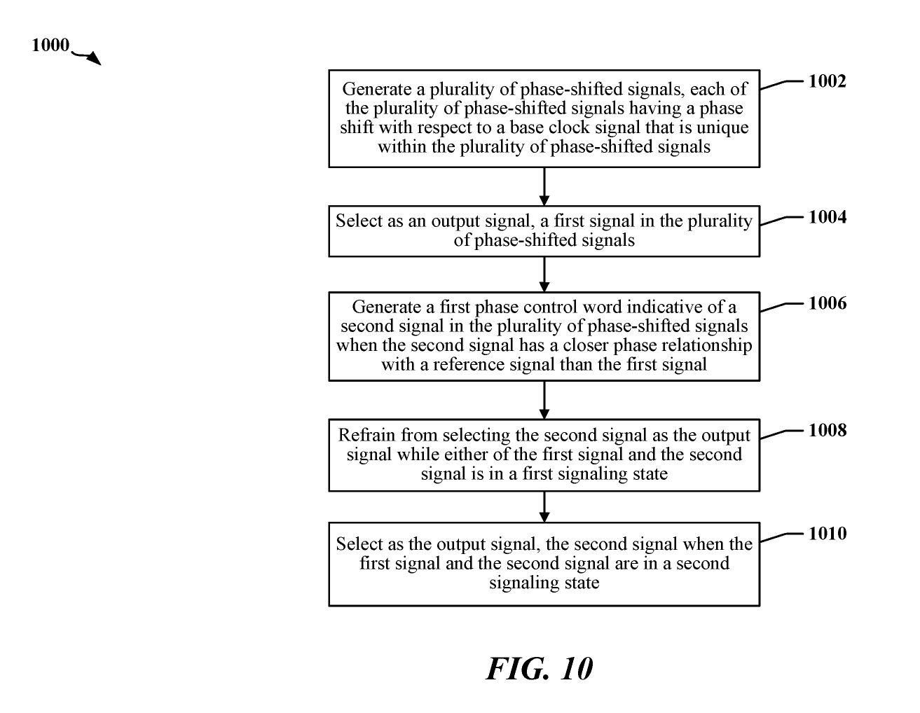

FIG. 10 is a flowchart 1000 for a method used to increase robustness of PLL operations. The method may be performed at a PLL device that include one or more phase rotator circuits used for clock generation.

At block 1002, the device may generate a plurality of phase-shifted signals. Each of the plurality of phase-shifted signals may have a phase shift with respect to a base clock signal that is unique within the plurality of phase-shifted signals. Each pair of signals in the plurality of phase-shifted signals may be separated by at least a minimum phase shift. In one example, the minimum phase shift may be calculated as (360°/p) where p represents the total number of phase-shifted signals in the plurality of phase-shifted signals. The first signal may be separated from the second signal by the minimum phase shift.

At block 1004, the device may select as an output signal, a first signal in the plurality of phase-shifted signals.

At block 1006, the device may generate a first phase control word indicative of a second signal in the plurality of phase-shifted signals when the second signal has a closer phase relationship with a reference signal than the first signal.

At block 1008, the device may refrain from selecting the second signal as the output signal while either of the first signal and the second signal is in a first signaling state. In one example, the first signaling state corresponds to a logic low state when the second signal lags the first signal. In another example, the first signaling state corresponds to a logic high state when the second signal leads the first signal.

At block 1010, the device may select as the output signal, the second signal when the first signal and the second signal are in a second signaling state.

In some instances, the device may generate a second phase control word configured to select a third signal in the plurality of phase-shifted signals. The device may select the second signal as the output signal in accordance with timing of the third signal. The timing of the third signal may cause the second signal to be selected as the output signal when the first signal and the second signal are in the second signaling state. In one example, the device may generate an indicator signal that indicates a phase relationship between the first signal and the second signal, and may use the indicator signal to generate the second phase control word. In another example, the third signal is phase shifted with respect to the first signal and with respect to the second signal.

In some examples, the device may generate a third phase control word configured to adjust phase of the base clock signal with respect to reference signal. The device may adjust timing of selection of the second signal as the output signal using the base clock signal. Latency in the output signal may be affected by adjusting the timing of selection of the second signal.

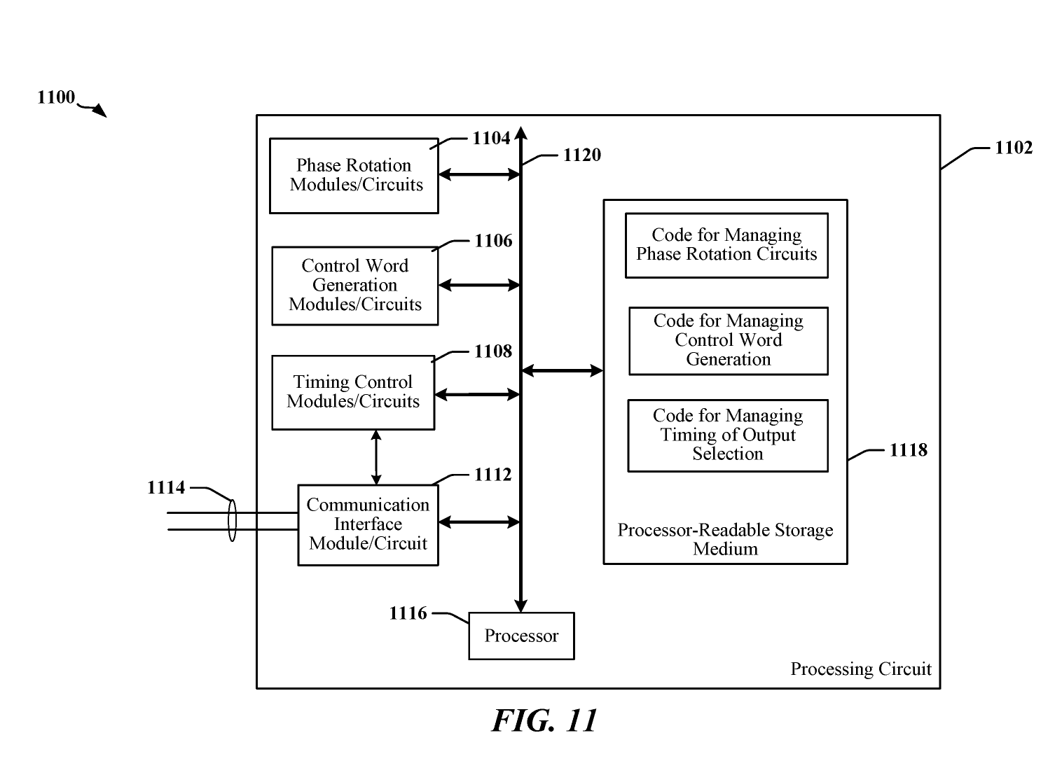

FIG. 11 is a diagram illustrating a simplified example of a hardware implementation for an apparatus 1100 employing a processing circuit 1102. The processing circuit typically has a processor 1116 that may include one or more of a microprocessor, microcontroller, digital signal processor, a sequencer and a state machine. The processing circuit 1102 may be implemented with a bus architecture, represented generally by the bus 1120. The bus 1120 may include any number of interconnecting buses and bridges depending on the specific application of the processing circuit 1102 and the overall design constraints. The bus 1120 links together various circuits including one or more processors and/or hardware modules, represented by the processor 1116, the modules or circuits 1104, 1106 and 1108 and the computer-readable storage medium 1118. The apparatus may have a connector 1112 adapted to communicate over a plurality of interconnects or wires 1114. In one example, the connector 1112 may be a Type-C connector adapted to couple the apparatus 1100 to another device in accordance with one or more USB protocols The bus 1120 may also link various other circuits such as timing sources, peripherals, voltage regulators, and power management circuits, which are well known in the art, and therefore, will not be described any further.

The processor 1116 is responsible for general processing, including the execution of software, code and/or instructions stored on the computer-readable storage medium 1118. The computer-readable storage medium may include a non-transitory storage medium. The software, when executed by the processor 1116, causes the processing circuit 1102 to perform the various functions described supra for any particular apparatus. The computer-readable storage medium may be used for storing data that is manipulated by the processor 1116 when executing software, including software, code and/or instructions loaded through the connector 1112. The processing circuit 1102 further includes at least one of the modules 1104, 1106 and 1108. The modules 1104, 1106 and 1108 may be software modules running in the processor 1116, resident/stored in the computer-readable storage medium 1118, one or more hardware modules coupled to the processor 1116, or some combination thereof. The modules 1104, 1106 and/or 1108 may include microcontroller instructions, state machine configuration parameters, or some combination thereof.

In one configuration, the apparatus 1100 includes phase rotation modules and/or circuits 1104 including a first phase rotation circuit configured to select an output signal from a plurality of phase-shifted signals derived from a base clock signal, each of the plurality of phase-shifted signals having a phase shift with respect to a base clock signal that is unique within the plurality of phase-shifted signals. The apparatus 1100 may include control word generation modules and/or circuits 1106 including a first control word generator adapted to produce phase control words that select an output signal from the plurality of phase-shifted signals as an output signal. The apparatus 1100 may include timing control modules and/or circuits 1108 including a timing control circuit adapted to provide a first control word produced by the first control word generator to the first phase rotation circuit after a delay when the first control word is configured to change the output signal by selecting a first signal that has a closer phase relationship with a reference signal than the output signal. The delay may prevent the timing control circuit from providing the first control word to the first phase rotation circuit while either of the first signal and the second signal is in a first signaling state.

In one configuration, each pair of signals in the plurality of phase-shifted signals is separated by at least a minimum phase shift. The first signal may be separated from the output signal by the minimum phase shift when the first control word is configured to change the output signal.

In another configuration, the first signaling state corresponds to a logic low state when the second signal lags the first signal.

In another configuration, the first signaling state corresponds to a logic high state when the second signal leads the first signal.

In another configuration, the apparatus 100 includes a second control word generator adapted to produce phase control words that select a sampling signal from the plurality of phase-shifted signals. The timing control circuit may be configured to control the delay using the sampling signal. The sampling signal may determine when the second signal is selected as the output signal. The second control word generator may be configured to generate an indicator signal that indicates a phase relationship between the first signal and the output signal. The indicator signal may be used to generate the phase control words that select a sampling signal. The third signal may be phase shifted with respect to the first signal and with respect to the output signal. The phase control word may be gated by the sampling signal until one or more resampled copies of the first phase control word match.

In another configuration, the apparatus 1100 includes a second control word generator adapted to produce phase control words that adjust phase of the base clock signal with respect to reference signal.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A clock generation method, comprising:
generating a plurality of phase-shifted signals, each of the plurality of phase-shifted signals having a phase shift with respect to a base clock signal that is unique within the plurality of phase-shifted signals;
selecting as an output signal, a first signal in the plurality of phase-shifted signals;
generating a first phase control word indicative of a second signal in the plurality of phase-shifted signals when the second signal has a closer phase relationship with a reference signal than the first signal;
refraining from selecting the second signal as the output signal while either of the first signal and the second signal is in a first signaling state; and
selecting as the output signal, the second signal when the first signal and the second signal are in a second signaling state.

2. The method of claim 1, wherein each pair of signals in the plurality of phase-shifted signals is separated by at least a minimum phase shift, and wherein the first signal is separated from the second signal by the minimum phase shift.

3. The method of claim 1, wherein the first signaling state corresponds to a logic low state when the second signal lags the first signal.

4. The method of claim 1, wherein the first signaling state corresponds to a logic high state when the second signal leads the first signal.

5. The method of claim 1, further comprising:
generating a second phase control word configured to select a third signal in the plurality of phase-shifted signals; and
selecting the second signal as the output signal in accordance with timing of the third signal.

6. The method of claim 5, wherein the timing of the third signal causes the second signal to be selected as the output signal when the first signal and the second signal are in the second signaling state.

7. The method of claim 5, further comprising:
generating an indicator signal that indicates a phase relationship between the first signal and the second signal; and
using the indicator signal to generate the second phase control word.

8. The method of claim 5, wherein the third signal is phase shifted with respect to the first signal and with respect to the second signal.

9. The method of claim 1, further comprising:
generating a third phase control word configured to adjust phase of the base clock signal with respect to reference signal.

10. The method of claim 1, further comprising:
adjusting timing of selection of the second signal as the output signal using the base clock signal,
wherein latency in the output signal is affected by adjusting the timing of selection of the second signal.

11. An apparatus, comprising:
a first phase rotation circuit configured to select an output signal from a plurality of phase-shifted signals derived from a base clock signal, each of the plurality of phase-shifted signals having a phase shift with respect to a base clock signal that is unique within the plurality of phase-shifted signals;
a first control word generator adapted to produce phase control words that select an output signal from the plurality of phase-shifted signals as an output signal; and
a timing control circuit adapted to provide a first control word produced by the first control word generator to the first phase rotation circuit after a delay when the first control word is configured to change the output signal by selecting a first signal that has a closer phase relationship with a reference signal than the output signal,
wherein the delay prevents the timing control circuit from providing the first control word to the first phase rotation circuit while either of the first signal and the output signal is in a first signaling state.

12. The apparatus of claim 11, wherein each pair of signals in the plurality of phase-shifted signals is separated by at least a minimum phase shift, and wherein the first signal is separated from the output signal by the minimum phase shift when the first control word is configured to change the output signal.

13. The apparatus of claim 11, wherein the first signaling state corresponds to a logic low state when the output signal lags the first signal.

14. The apparatus of claim 11, wherein the first signaling state corresponds to a logic high state when the output signal leads the first signal.

15. The apparatus of claim 11, further comprising:
a second control word generator adapted to produce phase control words that select a sampling signal from the plurality of phase-shifted signals,
wherein the timing control circuit is configured to control the delay using the sampling signal.

16. The apparatus of claim 15, wherein the sampling signal determines when the first signal is selected as the output signal.

17. The apparatus of claim 15, wherein the second control word generator is configured to generate an indicator signal that indicates a phase relationship between the first signal and the output signal, and wherein the indicator signal is used to generate the phase control words that select a sampling signal.

18. The apparatus of claim 15, wherein the sampling signal is phase shifted with respect to the first signal and with respect to the output signal.

19. The apparatus of claim 15, further comprising:
the phase control word is gated by the sampling signal until one or more resampled copies of the first phase control word match.

20. The apparatus of claim 11, further comprising:
a second control word generator adapted to produce phase control words that adjust phase of the base clock signal with respect to reference signal.

21. A clock generation apparatus, comprising:
means for generating a plurality of phase-shifted signals, each of the plurality of phase-shifted signals having a phase shift with respect to a base clock signal that is unique within the plurality of phase-shifted signals;
means for selecting an output signal from the plurality of phase-shifted signals, wherein a first signal in the plurality of phase-shifted signals is initially selected as the output signal; and
means for generating phase control words, wherein the means for generating phase control words is configured to generate a first phase control word that indicates a second signal in the plurality of phase-shifted signals when the second signal has a closer phase relationship with a reference signal than the first signal,
wherein the means for selecting the output signal from the plurality of phase-shifted signals is configured to:
refrain from selecting the second signal as the output signal while either of the first signal and the second signal is in a first signaling state; and
select the second signal as the output signal when the first signal and the second signal are in a second signaling state.

22. The apparatus of claim 21, wherein each pair of signals in the plurality of phase-shifted signals is separated by at least a minimum phase shift, and wherein the first signal is separated from the second signal by the minimum phase shift.

23. The apparatus of claim 21, wherein the first signaling state corresponds to a logic low state when the second signal lags the first signal.

24. The apparatus of claim 21, wherein the first signaling state corresponds to a logic high state when the second signal leads the first signal.

25. The apparatus of claim 21, wherein:
the means for generating phase control words is configured to generate a second phase control word that selects a third signal in the plurality of phase-shifted signals; and
wherein the means for selecting the output signal from the plurality of phase-shifted signals is configured to select the second signal as the output signal in accordance with timing of the third signal.

26. The apparatus of claim 25, wherein the timing of the third signal causes the second signal to be selected as the output signal when the first signal and the second signal are in the second signaling state.

27. The apparatus of claim 25, further comprising:
means for generating an indicator signal that indicates a phase relationship between the first signal and the second signal,
wherein the means for generating phase control words is configured to generate the second phase control word using the indicator signal.

28. The apparatus of claim 25, wherein the third signal is phase shifted with respect to the first signal and with respect to the second signal.

29. The apparatus of claim 21, further comprising:
means for generating a third phase control word configured to adjust phase of the base clock signal with respect to reference signal.

30. The apparatus of claim 21, further comprising:
means for adjusting timing of selection of the second signal as the output signal using the base clock signal,
wherein the means for adjusting the timing of selection of the second signal is configured to modify latency in the output signal by adjusting the timing of selection of the second signal.
